(19) United States
(12) Patent Application Publication
(10) Pub. No.: US 2025/0370333 A1
(43) Pub. Date: Dec. 4, 2025

(54) ORGANOMETALLIC PHOTORESIST COMPOSITIONS FOR PHOTOLITHOGRAPHY PATTERNING

(71) Applicant: Feng Lu, Irvine, CA (US)

(72) Inventor: Feng Lu, Irvine, CA (US)

(21) Appl. No.: 19/218,307

(22) Filed: May 25, 2025

Related U.S. Application Data
(60) Provisional application No. 63/653,376, filed on May 30, 2024.

(51) Int. Cl. G03F 7/004; H01L 21/027

(52) U.S. Cl. CPC G03F 7/0042; H01L 21/0274

(57) ABSTRACT

Organometallic photoresist compositions for photolithography patterning, particularly for extreme ultraviolet (EUV) radiation, are described. The organometallic photoresist compositions comprise a first organometallic (cyclopentadienyl)tin compound; a second organometallic compound represented by chemical formula CpₐM_{b}L_{c}, wherein M comprises Sb, In, Bi, Te, Zr, and Hf, Cp is cyclopentadienyl, L is ligand, a, b, c are integer and ≥1; a solvent; and/or an additive.

### CROSS REFERENCE TO RELATED APPLICATIONS

This application claims priority to U.S. provisional patent application No. 63/653,376, filed on May 30, 2024 to Lu, entitled “Organometallic photoresists compositions for photolithography patterning”, of which is entirely incorporated herein by reference.

### FIELD OF INVENTION

The present invention relates to organometallic photoresist compositions for photolithography patterning, particularly for extreme ultraviolet (EUV) radiation photolithography.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance, and ability to form thinner layer are important in photolithography.

Organometallic compounds have high ultraviolet light absorption because metals have high absorption capacity of ultraviolet radiation with various carbon-metal (C-M) bond dissociation energy (BDE), and then can be used as photoresists and/or the precursors for photolithography at smaller level (e.g., <7 nm), which is of great interests for radiation lithography. Among those promising advanced materials, particularly organometallic tin (organotin) compounds can provide photoresist patterning with significant advantages, such as improved resolution, sensitivity, etch resistance, and lower line width/edge roughness without pattern collapse because of strong EUV radiation absorption of tin, which have been demonstrated.

### SUMMARY

In a first aspect, the present invention pertains to organometallic photoresist compositions for photolithography patterning, particularly for extreme ultraviolet radiation (EUV), wherein organometallic photoresist contains cyclopentadienyl group. The present invention is to provide improved resolution sensitivity, etch resistance, and lower line width/edge roughness without pattern collapse for photolithography patterning.

In another aspect, the invention pertains to radiation sensitive organometallic photoresist compositions comprise a first organometallic (cyclopentadienyl) tin compound, a second organometallic compound representing by chemical formula CpₐM_{b}L_{c} wherein M comprises Sb, In, Bi, Te, Zr, and Hf, a solvent, and/or an additive; wherein Cp is cyclopentadienyl group, L is ligand, a, b, c are integral and ≥1. The photosensitivity and thermostability of organometallic photoresists determine high resolution and efficiency of photolithography.

The radiation sensitive organometallic photoresists become to insoluble, or un-sublimized/un-vaporized metallic complexes or polymetallic network complexes (e.g., metal oxides, or organometallic polymer) after exposing to ultraviolet light (e.g., EUV or DUV). Meanwhile unexposed organometallic photoresists can be removed by developer, or sublimation or vaporization under ambient vacuum and temperature (e.g., high vacuum and temperature), or vacuum treatment, without decomposition to form metallic complexes.

In an exemplary embodiment, the first organometallic (cyclopentadienyl) tin compound is one or more selected from below;

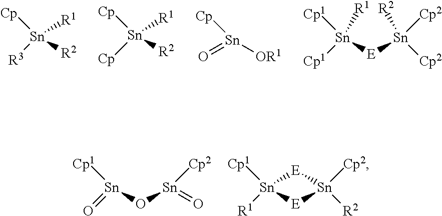

wherein Cp¹, Cp² are each independently cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers; R¹, R², R³ are each independently —X, -ER⁴, —N(R⁴)(R⁵), —OC(═O)R⁴, —(C═O)—R⁴, —N(R⁵)—(C═O)—R⁴, or —(C═O)—N(R⁴)(R⁵) group shown as below;

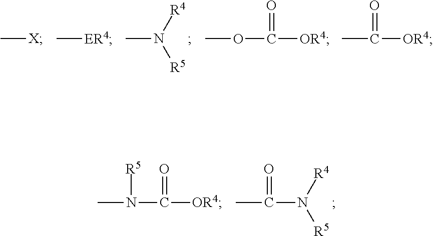

wherein R, R⁴, R⁵ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; X=F, Cl, Br, or I; E=O, S, Se, or Te.

In another exemplary embodiment, the second organometallic compound representing by chemical formula CpₐM_{b}L_{c} comprises Cp¹Sb(L¹)(L²), (Cp¹)(Cp²)SbL¹, Cp¹Bi(L¹)(L²), (Cp¹)(Cp²)BiL¹, Cp¹In(L¹)(L²), (Cp¹)(Cp²)InL¹, Cp¹TeL¹, (Cp¹)(Cp²)Zr(L¹)(L²), or (Cp¹)(Cp²)Hf(L¹)(L²) depicted as below:

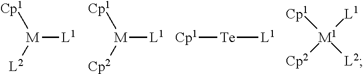

wherein Cp¹, Cp² are each independently cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers; M is Sb, Bi, or In, M¹ is Zr, or Hf; L¹, L² are each independently —X, -ER⁴, —N(R₄)(R₅), —OC(═O)R₄, —(C═O)—R₄, —N(R₅)—(C═O)—R₄, or —(C═O)—N(R₄)(R₅) group shown as below;

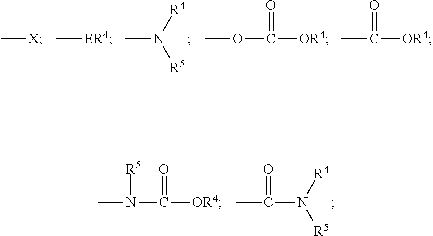

wherein R, R⁴, R⁵ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; X=F, Cl, Br, or I; E=O, S, Se, or Te.

In another aspect, the invention pertains to sublimation or vaporization development method under ambient vacuum and temperature (e.g., high vacuum and temperature), which may overcome the disadvantages or drawbacks from conventional wet or dry development method, such as pattern collapse and defects.

In a further aspect, the invention pertains to highly pure radiation sensitive organometallic cyclopentadienyl-containing compounds as photoresists, which may be suitable for EUV or DUV photolithography, and/or as the precursors for EUV or DUV photolithography. In some embodiments, organometallic cyclopentadienyl-containing photoresists can be sublimized or vaporized under ambient vacuum and temperature (e.g., high vacuum and temperature).

In other aspects, the present invention pertains to a method of photolithography patterning, including depositing an organometallic photoresist composition over a substrate, wherein the organometallic photoresist composition comprises a first organometallic (cyclopentadienyl) tin compound, a second organometallic compound representing by chemical formula CpₐM_{b}L_{c} wherein M comprising Sb, In, Bi, Te, Zr, and Hf, a solvent, and/or an additive; exposing the organometallic photoresist layer to actinic radiation to form a latent pattern; and developing the latent pattern by applying a developer, or sublimation, or vaporization to remove the unexposed or exposed portion of photoresists to form a photolithography pattern.

In an addition aspect, the present invention further pertains to a method of stabilization; wherein an organic additive stabilizes organometallic photoresist composition for photolithography patterning. Organic additive stabilization may overcome the disadvantages like poor stability and solubility, and/or short shelf time from non-stabilized conventional organotin photoresists. The method of stabilization comprises the addition of organic additive to stabilize the as-formed organometallic compound photoresists, and to prevent from aggregation occurred or precipitate formation. The aggregation and precipitation can lead to scums or defects on the surface of substrates during photolithography patterning. The organic additives contain various functional groups, such as —SH, —OH, —NH₂, —COOH, —CONH₂, including but not limited to, organic thiol, organic alcohol, organic amine, organic amide, organic carboxylic acid, organic phosphine, phosphine oxide, or phosphonic acid.

In a further aspect, the invention relates to radiation sensitive organometallic photoresist compositions, which can be efficiently patterned after exposure to extreme ultraviolet radiation (EUV), deep ultraviolet radiation (DUV), electron beam radiation, X-ray radiation, or ion-beam radiation, or other likes to form high resolution patterns with low line width roughness, high resolution, low dose and large contrast, such as for <7 nm.

### BRIEF DESCRIPTION OF THE DRAWINGS

FIG. 1 illustrates a flowchart of organometallic photoresist radiation photolithography patterning processing over the surface of semiconductor substrate.

### DETAILED DESCRIPTION

The present invention pertains to organometallic photoresist compositions for photolithography patterning, particularly for extreme ultraviolet radiation (EUV). The organometallic photoresist compositions comprise a first organometallic (cyclopentadienyl) tin compound, a second organometallic compound represented by chemical formula CpₐM_{b}L_{c} wherein M comprises Sb, In, Bi, Te, Zr, and Hf, a solvent, and/or an additive; wherein Cp is cyclopentadienyl group, L is ligand; a, b, c are integral and ≥1; wherein cyclopentadienyl comprises cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an amino, cyano, ether, ester, halide, nitro, silyl, thiol, or carbonyl group. The present invention is to provide a method of photolithography patterning of organometallic photoresist composition, particularly, suitable for EUV lithography (e.g., <7 nm). The method of photolithography patterning comprises depositing an organometallic photoresist composition over a substrate to form a photoresist layer after baking, exposing the photoresist layer to actinic radiation to form a latent pattern; and developing the latent pattern by applying a developer, or sublimation, or vaporization under vacuum to remove the unexposed or exposed portion of photoresists to form a photolithography pattern. In addition, organic molecules bearing various functional groups (e.g., —SH, —OH, —NH₂, —COOH, —CONH₂) may be used as stabilization additives. Organic molecules stabilized organometallic photoresists may have higher resolution, sensitivity, solubility, stability, shelf life, and lower line width roughness without pattern collapse during microelectronic patterning.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl” or “alkyl group” refers to a saturated linear or branched-chain hydrocarbon of 1 to 20 carbon atoms. The term “alkenyl” refers to an aliphatic hydrocarbon of 2 to 20 carbon atoms containing at least one carbon-carbon double bond. The term “alkynyl” refers to an aliphatic hydrocarbon of 2 to 20 carbon atoms containing at least one carbon-carbon triple bond. The term “cycloalkyl” refers to cyclic aliphatic hydrocarbon of 3 to 20 carbon atoms. The term “cycloalkenyl” refers to substituted and unsubstituted cyclic aliphatic unsaturated organic groups of 3 to 20 carbon atoms including at least one double carbon-carbon bond hydrocarbon. The term “aryl” refers to unsubstituted or substituted aromatic group with 6 to 20 carbon atoms. The term “alkylene” refers to a saturated divalent hydrocarbons by removal of two hydrogen atoms from a saturated hydrocarbons of 1 to 20 carbon atoms, e.g., methylene (—CH₂—), ethylene (—CH₂CH₂—), propylene (—CH₂CH₂CH₂—), or the like. The substituted groups include, but not limited to, amide, amine, cyano, ether, cyclic ether, ester, cyclic ester, halide, imine, nitro, silyl, thiol, or carbonyl group.

In some embodiments, cycloalkenyl group comprises substituted and unsubstituted C3 to C8 cyclic aliphatic unsaturated organic groups including at least one double bond, for example,

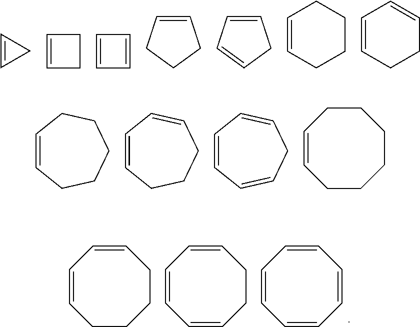

The term “amine” refers to primary (—NH₂), secondary (—NHR), or tertiary (—NR₂) amine group. The term “cyclic amine” refers to [R—NH—R′], wherein [R—R′] is cyclic substituted and unsubstituted C3 to C8 organic group, including, but not limited to:

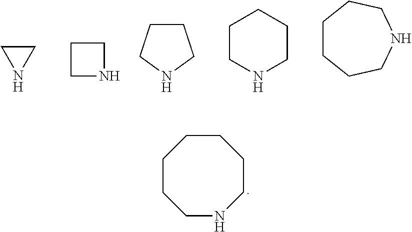

The term “ether” refers to the R—O—R′ group. The term “cyclic ether” refers to the [R—O—R′], wherein [R—R′] is cyclic substituted and unsubstituted C3 to C8 organic group, including, but not limited to:

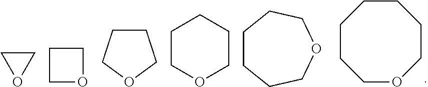

The term “ester” refers to the R—(C═O)—O—R′ group. The term “cyclic ester” refers to the [R—(C═O)—O—R′], wherein [R—R′] is cyclic substituted and unsubstituted C4 to C8 organic group, including, but not limited to:

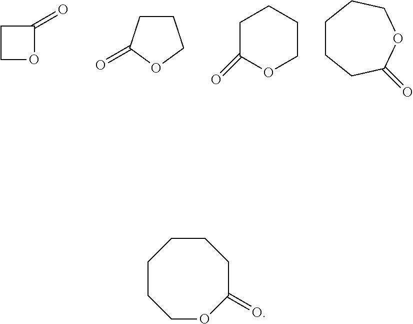

The term “halide” refers to the fluorine (F), chlorine (Cl), bromine (Br), or iodine (I). The term “nitro” refers to the —NO₂. The term “silyl” refers to the —SiR—, —SiR₂—, or —SiR₃ group. The term “thiol” refers to—SH group. The term “thiolate” refers to—SR group. The term “carbonyl” refers to the —C═O group. The term “oxo” refers to —O—, or ═O. In the above described, R, R′ are independently a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms.

In addition, in the present disclosure, the term “substituted” refers to replacement of a hydrogen atom with a C1 to C20 alkyl group, a C1 to C20 alkene group, a C1 to C20 alkyne group, a C1 to C20 cycloalkyl group, a C6 to C20 aryl group, or other relevant groups including, but not limited to, amide, amine, cyano, cyclic amine, ether, cyclic ether, ester, cyclic ester, halide, imine, nitro, silyl, thiol, or carbonyl group, for example, fluoroalkyl, fluorobenzyl, trifluoroacetic acid.

The terms “η¹” refers to one carbon atom bonded to one metal atom. The terms “η²” refers to two carbon atoms bonded to one metal atom. The terms “η³” refers to three carbon atoms bonded to one metal atom. The terms “η⁴” refers to four carbon atoms bonded to one metal atom. The terms “η⁵” refers to five carbon atoms bonded to one metal atom. In some embodiments, η⁵-compounds comprise sandwich or half-sandwich compounds.

EUV lithography is under the development for the mass production of next generation <7 nm node. EUV photoresists are required to achieve higher performance, higher sensitivity and resolution, and cost reduction.

EUV light has been applied for photolithography at about 13.5 nm. In some embodiments, the EUV light can be generated from Sn plasma or Xe plasma source excited using high energy lasers or discharge pulses.

For conventional organic polymer photoresists, if the aspect ratio, which is the height divided by width, is too large that would lead to pattern structures susceptible to collapse, and also associated with surface tension, which would limit the application for smaller features like <7 nm.

For small feature sizes like <7 nm, such as 1-3 nm, the conventional chemically amplified (CA) organic polymer photoresists encounter critical issues, such as poor EUV light absorption, low resolution, high line edge roughness (LER) or high line width roughness (LWR), increased pattern collapses and defects. In order to overcome the disadvantages from conventional organic polymer photoresists or inorganic photoresists, novel organometallic photoresists, or organometallic photosensitive compositions, particularly for EUV, have been called for.

In general, metal central plays the key role in determining the absorption of photo radiation.

Organometallic photoresists are used in EUV lithography because metals have high absorption capacity of EUV radiation. Radiation sensitivity and thermal-, oxygen- and moisture-stability are important for organometallic photoresists. Organometallic compounds usually are air-, water-, light-, or thermal-sensitive, which indicate organometallic compounds may be decomposed when exposed to air, water (moisture), light or heat under certain circumstance. As a result, the synthesis, isolation, or characterization of organometallic compounds usually are performed under inert atmosphere such as dinitrogen or argon, or avoiding the sunlight, or at low temperature. However, the “supposed disadvantages” of light-/thermal-sensitivity or light-/thermal-instability of some organometallic compounds might be advantages when compared to relevantly stable organic counterparts like organic polymer photoresists if considering sensitivity, performance, efficiency, cost, and convenience for photolithography patterning like EUV or DUV.

In some embodiments, organometallic photoresists may adsorb moisture and oxygen, which may result in decreasing stability, as well decreasing solubility in developer solutions. In addition, in some embodiments, photoresist layer may outgas volatile components prior to the radiation exposure and development operations, which may negatively affect the lithography performance, pattern collapse and increase defects.

The physical and chemical properties of organometallic compounds which are suitable for photoresists determine the relevant properties for photolithography, particularly for EUV and DUV, wherein bond dissociated energy (BDE) of M-C(metal-carbon bond) plays the key role. The metal-bonded organic ligands (M-R, M=metal, R=cleavable or hydrolysable ligands) may also influence the relevant absorption through M-C bonding.

Among various metals, tin (Sn), bismuth (Bi), antimony (Sb), indium (In), and tellurium (Te) have strong absorption of extreme ultraviolet light at 13.5 nm. Other metals such as zirconium (Zr), hafnium (Hf), vanadium (V), titanium (Ti), gallium (Ga), tungsten (W), or molybdenum (Mo), also have good absorption at specialized wavelength, for example at 193 nm, or 248 nm.

In some embodiments, a blend of organometallic compounds as photoresists comprises a first organometallic tin compound, and a second organometallic compound represented by chemical formula R′ₐM_{b}L_{c} wherein M comprising antimony (Sb), indium (In), bismuth (Bi), tellurium (Te), zirconium (Zr), hafnium (Hf), titanium (Ti), vanadium (V), tungsten (W), molybdenum (Mo), gallium (Ga), manganese (Mn), chromium (Cr), selenium (Se), or germanium (Ge); R′ is a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; and a, b, c are integer and ≥1. In some embodiments, R′ is cyclopentadienyl group, wherein cyclopentadienyl is cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms

Tin atom provides strong absorption of extreme ultraviolet (EUV) light at 13.5 nm, therein tin cations can be selected based on the desired radiation and absorption cross section. Meanwhile the organic ligands bonded to tin also has absorption of EUV light. Therefore, the tuning and modification of organic ligands can change sensitivity, radiation absorption, or the desired control of material properties.

The bond dissociation energy (BDE) of Sn—C bond determines light absorption wavelength, corresponding smaller features, and patterned structures.

Organotin photoresists have excellent (e.g., suitable) sensitivity to high energy light (e.g., EUV, DUV, X-ray, or laser) due to tin strong absorption of extreme ultraviolet (EUV) at about 13.5 nm. Accordingly, organotin photoresists have improved sensitivity, resolution, stability compared to conventional organic polymer or inorganic photoresists.

Organotin compound photoresists contain organic ligands, Sn—C bond, or Sn—O bond, or Sn—S bond, or Sn—Se bond, or Sn—Te bond, or Sn—N bond, or Sn—X bond (X=F, Cl, Br, or I), or Sn—O—Sn bond providing desirable radiation sensitive and stabilization for precursor metal cations. The organotin compound photoresists possess excellent properties for photolithographic patterning.

In some embodiments, a blend of volatile or sublimized-available organometallic compounds as photoresists can perform in situ ultraviolet light-induced radiation reaction to form non-sublimized, non-volatile or insoluble complexes, including but not limited to oxo/hydroxyl, polyatomic complexes, metal oxo or hydroxyl network, or organometallic polymer, in the presence of electromagnetic radiation such as EUV/DUV light or electron beam, which possess the feature characterizes for small pitch like <7 nm. Meanwhile, the unexposed portion of volatile blend organometallic photoresists can be removed by vacuum at appropriate temperature like 20-300° C. However, in the absence of ultraviolet light, no reactions, including thermal or radiation reactions, of blend of organometallic photoresists would occur under ambient conditions. In some embodiments, the in situ radiation reaction may be carried out in solvents like organic solvents, which is spray on the substrate surface after deposition of organometallic photoresists, or by spinning-on deposition as solution composition.

In the present invention, organometallic photoresist composition comprises: a first organometallic (cyclopentadienyl) tin compound; a second organometallic compound represented by chemical formula CpₐM_{b}L_{c}, wherein M comprises Sb, In, Bi, Te, Zr, and Hf, Cp is cyclopentadienyl, L is ligand, a, b, c are integer and ≥1; a solvent; and/or an additive.

Examples of specific the first organometallic (cyclopentadienyl) tin photoresist that may be used in implementations of the invention, is one or more selected from below:

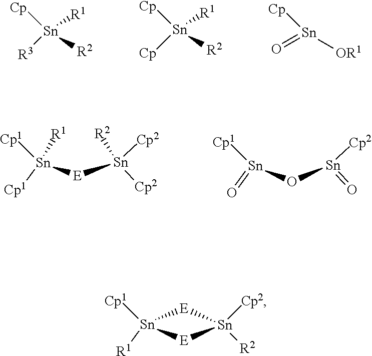

wherein Cp¹, Cp² are each independently cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers; R₁, R₂, R₃ are each independently —X, -ER⁴, —N(R₄)(R₅), —OC(═O)R₄, —(C═O)—R₄, —N(R₅)—(C═O)—R₄, or —(C═O)—N(R₄)(R₅) group shown as below,

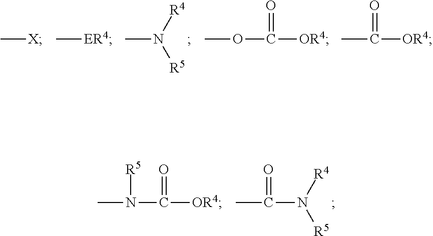

wherein R, R⁴, R⁵ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; X=F, Cl, Br, or I; E=O, S, Se, or Te.

Examples of specific the second organometallic compound represented by chemical formula CpₐM_{b}L_{c} comprises Cp¹Sb(L¹)(L²), (Cp¹)(Cp²)SbL¹, Cp¹Bi(L¹)(L²), (Cp¹)(Cp²)BiL¹, Cp¹In(L¹)(L²), (Cp¹)(Cp²)InL¹, Cp¹TeL¹, (Cp¹)(Cp²)Zr(L¹)(L²), or (Cp¹)(Cp²)Hf(L¹)(L²) depicted as below:

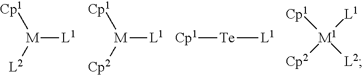

wherein Cp¹, Cp² are each independently cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers; M is Sb, Bi, or In, M¹ is Zr, or Hf; wherein L¹, L² are each independently —X, -ER⁴, —N(R⁴)(R⁵), —OC(═O)R⁴, —(C═O)—R⁴, —N(R⁵)—(C═O)—R⁴, or —(C═O)—N(R⁴)(R⁵) group shown as below,

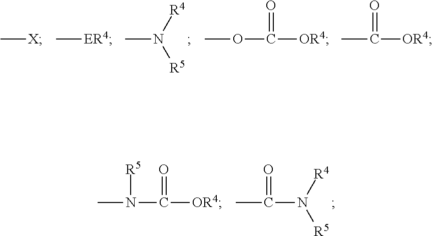

wherein R⁴, R⁵ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; X=F, Cl, Br, or I; E=O, S, Se, or Te.

For example, in some embodiments, R¹, R², R³, R⁴, R⁵ are each independently H, an alkyl, alkenyl, alkynyl, cycloalkyl, cycloalkenyl, or aryl group, for example, methyl (Me), ethyl (Et), isopropyl (i-Pr), n-butyl (n-Bu), t-butyl (t-Bu), t-amyl, s-butyl, pentyl, hexyl, neopentyl (Neo), cyclohexyl, cyclopentyl, cyclobutyl, cyclopropyl, cyclopentadienyl, phenyl (Ph), or benzyl (Ben) group. In some embodiments, R¹, R², R³, R⁴, R⁵ comprise fluorine (F) or fluorinated.

As one of ordinary skill in the art will recognize, the chemical compounds listed here are merely intended as illustrated examples of organometallic compounds as photoresists, and/or as precursors, and are not intended to limit the embodiments to only those organometallic compounds as photoresists, and/or precursors specifically described. Rather, any suitable organometallic compound photoresist may be used, and all such organometallic compound photoresists are fully intended to be included within the scope of the present embodiments.

Organometallic photoresists bearing cyclopentadienyl include hapticity of η¹, η², η³, η⁴, or η⁵ of isomers. In some embodiments, organometallic compound is η¹ (bearing σ bonding), or η⁵ (bearing π bonding, e.g., sandwich or half-sandwich) hapticity depicted as below (M=metal);

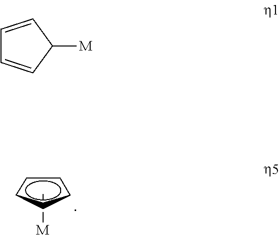

In some embodiments, organometallic compounds comprises cyclopentadienyl C₅H₅ group, or substituted C₅H₄R, C₅H₃R₂, C₅H₂R₃, C₅HR₄, or C₅R₅ group with hapticity of η¹, η², η³, η⁴, or η⁵. A person of ordinary skills in the art will recognize that the structures of cyclopentadienyl or substituted cyclopentadienyl with hapticity of η¹, η², η³, η⁴, or η⁵ of isomers within the explicit ranges of above are contemplated and are within the present disclosure.

In some embodiments, organometallic compounds contain cyclopentadienyl C₅H₅, or substituted cyclopentadienyl C₅H₄R, C₅H₃R₂, C₅H₂R₃, C₅HR₄, or C₅R₅ group, wherein R includes, but not limited to, a methyl, ethyl, isopropyl, n-butyl, t-butyl, t-amyl, s-butyl, pentyl, hexyl, neopentyl, cyclohexyl, cyclopentyl, cyclobutyl, cyclopropyl, phenyl, or benzyl group.

Cyclopentadienyl group (C₅R₅, or Cp) may impart photosensitivity to the compounds, and the Cₚ—Sn bond formed may promote suitable solubility in an organic solvent to cyclopentadienyl-containing organotin compounds. Accordingly, these Cp-Sn bond containing organotin compounds according to an embodiment may have improved sensitivity, resolution and stability, and may suitable for EUV photoresists, and/or the precursors for EUV lithography to form tin oxide or tin oxide hydroxide film or organometallic polymer.

The organotin compounds contain cyclopentadienyl-Sn bond (Cp-Sn bond). Cp-Sn bond is sensitive to UV light and occurs the radiation disruption to generate free radical when exposures to UV light, which has been demonstrated, for example, P. J. Baker, A. G. Davies, M.-W. Tse, “The Photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl) tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅· radical. This study demonstrated cyclopentadienyl (C₅H₅) group or substituted cyclopentadienyl (C₅R₅) group has higher UV light sensitivity compared with alkyl (e.g., methyl, butyl) groups under identical conditions. This property is beneficial for decreasing EUV light dose and increasing resolution.

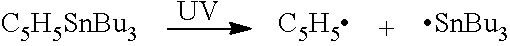

Organotin compounds contain tin and C—Sn bond, therefore may absorb extreme ultraviolet light at 13.5 nm.

Organotin compound photoresists contain cyclopentadienyl (Cp), or substituted-cyclopentadienyl group, π bond, C—Sn bond and related interaction and may have excellent (e.g., suitable) sensitivity to high energy light (e.g., EUV, or DUV) due to tin absorption high energy EUV ray at 13.5 nm. Accordingly, the related solution compositions may have improved resolution, sensitivity, and stability compared with organic polymer or inorganic photoresists such as metal oxides.

In some embodiments, organotin compound photoresists may have excellent sensitivity to EUV radiation light due to the tin absorption high energy EUV ray at 13.5 nm (low expose dose photoresist, e.g., <20 mJ/cm²), and the disruption of Cp-Sn bond to form free radical, tin oxide and relative products, and toughness; low or free pattern defectivity at nanoscale. Accordingly, the solution composition of organotin compound photoresists may have tight pitch (e.g., <10 nm), and may sustain the yield and deliver high resolution.

In some embodiments, organometallic compound photoresists comprise various functional groups, including but not limited to, ether, thiol, silyl, keto, cyano, carbonyl, or halogenated group, or combinations thereof.

Organometallic (cyclopentadienyl) tin compounds contain cyclopentadienyl group, Sn—C, or Sn—N, or Sn—O, or Sn—S, or Sn—Se, or Sn—Te bond with different bond dissociation energy (BDE) and sensitivity to extreme ultraviolet light.

Organometallic photoresist composition according to embodiments of the present disclosure may have relatively improved etch resistance, sensitivity and resolution, compared to related conventional organic polymer and inorganic resists.

Organometallic compounds as photoresists are soluble in appropriate organic solvents for further photolithography pattern processing.

In some embodiments, organometallic compound photoresists are soluble in appropriate organic solvents with improved uniformity for photolithography pattern processing. The solution compositions can be formed by dissolving organometallic compound photoresists in organic solvents, including but not limit to, pentane, hexane, cyclohexane, dichloromethane (CH₂Cl₂), chloroform (CHCl₃), tetrahydrofuran, dimethoxyethane (DME), dimethylformamide (DMF), dimethyl sulfoxide (DMSO), alcohols (e.g., 4-methyl-2-pentenol, methanol, ethanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. A person of ordinary skills in the art will recognize that the choice of solvents and solution composition components within the explicit ranges of above are contemplated and are within the present disclosure.

Organometallic photoresist composition may include 0.1 wt % to 60 wt % of the organometallic compounds, based on the total weight of the organometallic photoresist composition. A person of ordinary skills in the art will recognize that the samples, concentrations, and amounts of organotin compounds within the explicit ranges of above are contemplated and are within the present disclosure.

In some embodiments, the solution composition of organometallic compound photoresists containing cyclopentadienyl or substituted-cyclopentadienyl group, according to embodiments of the present disclosure, may have relatively improved etch resistance, sensitivity and resolution, compared to related conventional organic polymer or inorganic photoresists.

In some embodiments, the first organometallic (cyclopentadienyl) tin compound, and the second organometallic compound represented by chemical formula CpₐM_{b}L_{c}, may be used as precursors to prepare other organometallic photoresists, or organometallic photoresist compositions, for example, hydrolysis with water or moisture to form organometallic cluster photoresist, or reaction with oxygen sources such as oxygen, air, or hydroperoxide.

In some embodiments, an organometallic photoresist precursor solution deposits over the surface of substrate or layer to form photoresist layer through in situ hydrolysis with water, or alternative bases like tetramethyl ammonium hydroxide. The baking of the formed photoresist layer at an elevated temperature result in hydrolysis of organometallic compound and subsequent condensation to form organometallic oxide hydroxide clusters. After exposure to EUV lithography or e-beam lithography, patterning radiation causes M-C bond cleavage and crosslinking of the organometallic oxide hydroxide clusters in the exposed portions of photoresists, and then resulted in a stable metal oxide (MOₓ).

The radiation sensitive organometallic photoresists comprise polynuclear oxo or oxo-hydroxide networks, and/or alkyl ligands. However, the poor stability of conventional organometallic or organometallic cluster photoresists in solution after aged would lead to aggregation or precipitation with short shelf life for photolithography, which then would result in scums or defects in photolithography patterning.

In some embodiments, organometallic photoresist compositions may also contain additives such as resin, in addition to photoresists and organic solvents.

In some embodiments, the addition of additives may increase the stability of the radiation sensitive organometallic photoresist compositions. In some embodiments, the stability of organometallic photoresists in solution can be improved by organic molecules as stabilizers. The organic molecules-stabilized organometallic photoresists possess improved stability, solubility, uniformity, or shelf life for photolithography patterning.

In some embodiments, organic molecule as stabilizing additive includes, but not limited to, organic thiol, organic alcohol, organic amine, organic amide, organic carboxylic acid, organic phosphine, phosphine oxide, or organic phosphonic acid. A person of ordinary skills in the art will recognize that organic molecules, concentrations, and solution composition components within the explicit ranges of above are contemplated and are within the present disclosure.

In some embodiments, the resin may be organic polymer, and/or small organic aromatic molecules. In some embodiments, the resin may be volatile under vacuum.

In some embodiments, organic molecules stabilizers may be adsorbed, grafted, immobilized, anchored, or coordinated on organometallic compound photoresists as supports. For example, organic thiol or thiolate may coordinate with tin of organotin to form Sn—S bond.

The solution composition of organometallic compound photoresists can be utilized for photolithography patterning including extreme ultraviolet radiation (EUV) (13.5 nm), deep ultraviolet radiation (DUV), such as KrF excimer laser (248 nm), or ArF excimer laser (193 nm), e-beam radiation, X-ray radiation, or ion-beam radiation for further processing and patterning.

The general photolithography process comprises (1) forming an organometallic compound photoresist composition; (2) depositing photoresist composition over a substrate (e.g., silicon, silicon oxide) to form a thin film; (3) then pre-exposure baking at appropriate temperature; (4) exposing to actinic radiation (e.g., EUV) to form a latent image, followed by after post-exposure baking; (5) then developing with a developer (e.g., aqueous basic/acid solutions or organic solvents); or sublimation, or evaporation under vacuum to remove the selected portion of photoresists; (6) and then rinsing with solvent to produce to form a photolithography pattern.

The present invention encompasses organometallic photoresist compositions for photolithography patterning. Herein organometallic photoresists comprise a blend of (cyclopentadienyl) tin compound, organometallic CpₐM_{b}L_{c} compound (M=Sb, In, Bi, Te, Zr, and Hf). The photolithography patterning comprises forming an organometallic photoresist composition; wherein the forming the organometallic photoresist composition comprises a blend of organometallic compounds, a solvent, and/or an additive; organometallic compound photoresist may be stabilized by organic molecules as additives. The formed organometallic photoresist composition is then deposited over a substrate such as silicon, silicon oxide to form photoresist layer. After baking at appropriate temperature, the organometallic photoresist layer is exposed to actinic radiation to form a latent pattern. The formed latent pattern is developed by applying a developer, or sublimation, or vaporization under vacuum to remove the unexposed, or exposed portion of photoresists to form a photolithography pattern.

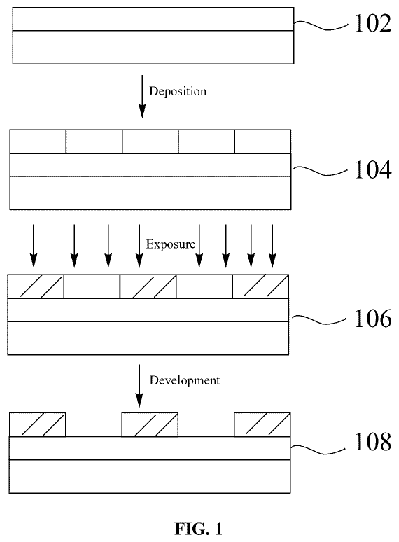

A method of forming photolithography pattern using the organometallic photoresist composition is illustrated by FIG. 1. The photolithography process described by FIG. 1, is to deposit photoresist over a substrate 102 to form a thin photoresist layer 104; after pre-exposure baking, the formed layer is exposed to actinic radiation to form a latent image 106; after post-exposure baking, the latent is developed by the appropriate developer, such as aqueous basic/acid solutions or organic solvents, to produce the developed resist photolithography pattern 108.

In an embodiment, organometallic photoresist compositions are deposited on a surface of semiconductor substrate by wet deposition like spin-on coating, spray coating, dip coating, or knife edge coating. In another embodiment, organometallic photoresist is deposited by chemical vapor deposition (CVD), atomic layer deposition (ALD), or physical vapor deposition.

Wet and dry deposition or coating methods may be carried out on the surface of semiconductor substrate. The general wet coating of radiation sensitive organometallic photoresists on the surface of semiconductor substrate includes spin-on coating, spray coating, dip coating, vapor deposition, knife edge coating, inkjet printing, screen printing, and the like.

In some embodiments, the conventional spin-on coating method is used for deposition of organometallic photoresists on the surface of semiconductor substrates to form a thin film for photolithography. Under this circumstance, the followed procedure of post-apply backed (PAB) on a hot plate at ambient temperature like 100° C. under inert atmosphere (e.g., dinitrogen) with regular pressure will be controlled to avoid the potential photoresist sublimation at the point temperature and then decrease the thickness of photoresist, followed by defects generation or pattern collapses.

In some embodiments, organometallic photoresists may be deposited on the semiconductor substrate through dry deposition method like chemical vapor deposition, physical vapor deposition, or atomic layer deposition without decomposition.

In some embodiments, the advantages of vapor and atomic layer deposition methods may improve the uniformity of thickness and composition, reduce the photoresist film defect density.

In some embodiments, the organometallic photoresist precursors suitable for chemical vapor deposition and atomic layer deposition can form metal oxide film through decomposition.

In some embodiments, after exposure, the exposed and unexposed portion of organometallic photoresists possess different chemical and physical properties. Organic ligands of organometallic photoresists can be cleaved to form metal oxide or polynuclear oxo/hydroxo network patterns. The unexposed portion of photoresists can be removed by the developer according to different features, solubility and properties. In an embodiment, the developer is a wet developer such as organic solvent, or aqueous solution. In another embodiment, the developer is a dry developer such as Cl₂, CH₂Cl₂, BF₃, BCl₃, CF₄, CCl₄, or HBr.

The development process is to either remove the exposed portion to form the positive tone pattern or unexposed portion to form negative tone pattern by different developer compositions. The contact of the pattered coating material or latent image with developer solvents will perform the target.

In some embodiments, the general wet developer compositions can be neutral, basic, acidic aqueous solutions, or organic solvents at low to high concentrations. The temperature for development process can be high or low. The temperature can be applied for the control of the rate or kinetics of development process as required.

In some embodiments, the general wet liquid solvent developer composition comprises an organic solvent blend. Non-limiting examples of organic solvents used in the method of forming patterns according to an embodiment may include, but not limited to, ketones (e.g., acetone, 2-heptanone, methylethylketone, cyclohexanone, 2-pyrrolidone, 1-ethyl-2pyrrolidone, and/or the like), alcohols (e.g., methanol, ethanol, 1-propanol, isopropanol, 1-butanol, 4-methyl-2-propanol, 1,2-propanediol, 1,2-hexanediol, 1,3-propanediol, pentanol, 2-heptanol, and/or the like), esters (e.g., ethyl acetate, n-butyl acetate, butyrolactone, propylene glycol methyl ether, ethylene glycol, propylene glycol, glycerol, ethylene glycol methyl ether, and/or the like), aromatic solvents (e.g., benzene, toluene, xylene), acid (e.g., formic acid, acetic acid, oxalic acid, 2-ethylhexanonic acid), and combinations thereof.

In some embodiments, the conventional wet development process may be replaced by sublimation or vaporization under vacuum at appropriate temperature, which can reduce the pattern collapse. For <7 nm pitch pattern, the issues from wet solvents development method after exposure like wetting and solvent surface tension effect may block the removal of unexposed portion of photoresist between two adjacent pitches at pretty small scale like ≤3 nm.

In some embodiments, the sublimation or vaporization ability and thermostability without decomposition under vacuum at appropriate temperature for radiation sensitive organometallic photoresists play the key role in determining the relevant development method.

The development method of sublimation or vaporization under vacuum may enhance pattern fidelity and eliminate microbridge defects, due to no usage of liquid solvent or gaseous. The sublimation or vaporization development method may significantly improve the efficiency, resolution and products ratios, and while reduce the cost including environmental concerns and waste treatment like water consuming and waste water/organic solvent treatment.

The desirable features of organometallic photoresists or precursors possess, sufficient volatility or sublimation ability for vapor-phase transportation, thermal stability to avoid the premature decomposition, and appropriate reactivity with co-precursor to form the target product in the presence of UV/EUV light radiation.

In some embodiments, the developing method is sublimation or evaporation under high reduced pressure in the range of 0.00001 torr to 100 torr, and/or at temperature in the range of 20 to 300° C. A person of ordinary skills in the art will recognize that the reduced pressures, and temperatures within the explicit ranges of above are contemplated and are within the present disclosure.

The invention pertains to the methods for preparation and purification of organometallic compounds as photoresists. In some embodiments, all chemical manipulations, including preparation and purification, are performed under an inert atmosphere of purified nitrogen or argon in dry and degassed solvents by employing standard Schlenk techniques. The methods for purification of organometallic compounds comprise distillation, extraction, filtration, recrystallization, column chromatography, coordination, sublimation, or combinations thereof.

In addition, organometallic photoresist compositions for photolithography patterning according to an embodiment is not necessarily limited to negative tone image but may be formed to have a positive tone image.

The advantages of organometallic photoresists are obvious as above discussed, compared to organic polymer photoresist or inorganic photoresists. However, it will be understood that not all the advantages have been necessarily discussed herein to include all embodiments or examples, other embodiments or examples may offer different advantages.

Hereinafter, the present invention is described in more details through embodiments and examples regarding of organometallic photoresist compositions for photolithography patterning. However, the present invention is not limited by the embodiments and examples. A person of ordinary skills in the art will recognize that the samples and solution composition components within the explicit ranges of above are contemplated and are within the present disclosure.

It is understood that the above described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the spirit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organometallic photoresist composition, comprising: a first organometallic (cyclopentadienyl) tin compound; a second organometallic compound represented by chemical formula CpₐM_{b}L_{c}, wherein M comprises Sb, In, Bi, Te, Zr, and Hf, Cp is cyclopentadienyl, L is ligand, a, b, c are integer and ≥1;
a solvent; and/or an additive.

2. The organometallic photoresist composition of claim 1, wherein the first organometallic (cyclopentadienyl) tin compound is one or more selected from below: 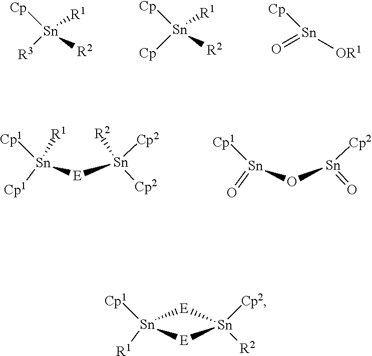
wherein Cp¹, Cp² are each independently cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers; R¹, R², R³ are each independently —X, -ER⁴, —N(R₄)(R₅), —OC(═O)R₄, —(C═O)—R₄, —N(R₅)—(C═O)—R₄, or —(C═O)—N(R₄)(R₅) group shown as below, 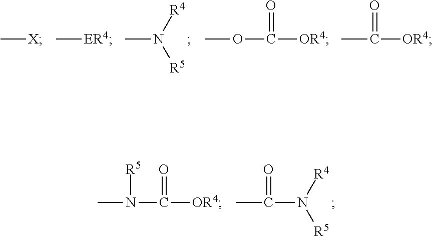
wherein R, R⁴, R⁵ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, X=F, Cl, Br, or I, E=O, S, Se, or Te.

3. The organometallic photoresist composition of claim 1, wherein the second organometallic compound represented by chemical formula CpₐM_{b}L_{c} comprises Cp¹Sb(L¹)(L²), (Cp¹)(Cp²)SbL¹, Cp¹Bi(L¹)(L²), (Cp¹)(Cp²)BiL¹, Cp¹In(L¹)(L²), (Cp¹)(Cp²)InL¹, Cp¹TeL¹, (Cp¹)(Cp²)Zr(L¹)(L²), or (Cp¹)(Cp²)Hf(L¹)(L²) depicted as below: 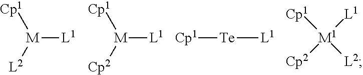
wherein Cp¹, Cp² are each independently cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers; M is Sb, Bi, or In, M¹ is Zr, or Hf.

4. The organometallic photoresist composition of claim 3, wherein L¹, L² are each independently —X, -ER⁴, —N(R⁴)(R⁵), —OC(═O)R⁴, —(C═O)—R⁴, —N(R⁴)—(C═O)—R⁵, or —(C═O)—N(R⁴)(R⁵) group, wherein R, R⁴, R⁵ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; X=F, Cl, Br, or I; E=O, S, Se, or Te.

5. The organometallic photoresist composition of claim 1, wherein the solvent comprises benzene, toluene, xylene, tetrahydrofuran, dimethoxyethane, methanol, 4-methyl-2-pentano, ethanol, propanol, butanol, or combinations thereof.

6. The organometallic photoresist composition of claim 1, wherein the photoresist is for extreme ultraviolet lithography, deep ultraviolet lithography, e-beam radiation, X-ray radiation, or ion-beam radiation.

7. A method of photolithography patterning, comprising:
depositing an organometallic photoresist composition over a substrate to form an organometallic photoresist layer;
exposing the organometallic photoresist layer to actinic radiation to form a latent pattern; and
developing the latent pattern by applying a developer, or sublimation, or vaporization to remove selected portion of photoresist to form a photolithography pattern.

8. The method of claim 7, wherein the organometallic photoresist composition comprises a first organometallic (cyclopentadienyl) tin compound; a second organometallic compound represented by chemical formula CpₐM_{b}L_{c}, wherein M comprises Sb, In, Bi, Te, Zr, and Hf, Cp is cyclopentadienyl, L is ligand, a, b, c are integer and ≥1; a solvent, and/or an additive.

9. The method of claim 8, wherein the first organometallic (cyclopentadienyl) tin compound is one or more selected from below: 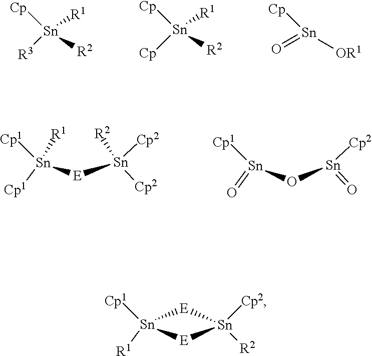
wherein Cp¹, Cp² are each independently cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers; R¹, R², R³ are each independently —X, -ER⁴, —N(R⁴)(R⁵), —OC(═O)R⁴, —(C═O)—R⁴, —N(R⁵)—(C═O)—R⁴, or —(C═O)—N(R⁴)(R⁵) group, wherein R, R⁴, R⁵ is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, X=F, Cl, Br, or I, E=O, S, Se, or Te.

10. The method of claim 8, wherein the second organometallic compound CpₐM_{b}L_{c} comprises Cp¹Sb(L¹)(L²), (Cp¹)(Cp²)SbL¹, Cp¹Bi(L¹)(L²), (Cp¹)(Cp²)BiL¹, Cp¹In(L¹)(L²), (Cp¹)(Cp²)InL¹, Cp¹TeL¹, (Cp¹)(Cp²)Zr(L¹)(L²), or (Cp¹)(Cp²)Hf(L¹)(L²) depicted as below: 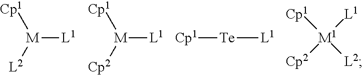
wherein Cp¹, Cp² are each independently cyclopentadienyl C₅H₅ group, or substituted cyclopentadienyl C₅H₄R, C₅H₃R₂, CH₂R₃, C₅HR₄, or C₅R₅ group with hapticity of η¹, η², η³, η⁴, or η⁵ of isomers; R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; M is Sb, Bi, or In, M¹ is Zr, or Hf.

11. The method of claim 10, wherein L¹, L² are each independently —X, -ER⁴, —N(R⁴)(R⁵), —OC(═O)R⁴, —(C═O)—R⁴, —N(R⁵)—(C═O)—R⁴, or —(C═O)—N(R⁴)(R⁵) group, wherein R⁴, R⁵ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; X=F, Cl, Br, or I; E=O, S, Se, or Te.

12. The method of claim 7, wherein the organometallic photoresist composition is deposited over a surface of semiconductor substrate by chemical vapor deposition, physical vapor deposition, atomic layer deposition, or spin-on coating.

13. The method of claim 7, wherein the actinic radiation is extreme ultraviolet radiation, deep ultraviolet radiation, e-beam radiation, X-ray radiation, or ion-beam radiation.

14. The method of claim 7, wherein the sublimation, or vaporization is carried out under vacuum ranging from 0.00001 torr to 100 torr, and/or a temperature ranging from 20° C. to 300° C.

15. An organometallic photoresist, comprising: a first organometallic (cyclopentadienyl) tin compound; a second organometallic compound CpₐM_{b}L_{c}, wherein M comprises Sb, In, Bi, Te, Zr, and Hf, Cp is cyclopentadienyl, L is ligand, and a, b, c are integer and ≥1.

16. The organometallic photoresist of claim 15, wherein the second organometallic compound CpₐM_{b}L_{c} is one or more selected from the group of Cp¹Sb(L¹)(L²), (Cp¹)(Cp²)SbL¹, Cp¹Bi(L¹)(L²), (Cp¹)(Cp²)BiL¹, Cp¹In(L¹)(L²), (Cp¹)(Cp²)InL¹, Cp¹TeL¹, (Cp¹)(Cp²)Zr(L¹)(L²), or (Cp¹)(Cp²)Hf(L¹)(L²) depicted as below:

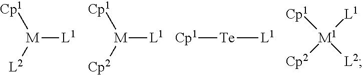

17. The organometallic photoresist of claim 16, wherein Cp¹, Cp² are each independently cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers; R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; M is Sb, Bi, or In, M¹ is Zr, or Hf.

18. The organometallic photoresist of claim 16, wherein L¹, L² are each independently —X, -ER⁴, —N(R⁴)(R⁵), —OC(═O)R⁴, —(C═O)—R⁴, —N(R⁵)—(C═O)—R⁴, or —(C═O)—N(R⁴)(R⁵) group, wherein R⁴, R⁵ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; wherein X=F, Cl, Br, or I; E=O, S, Se, or Te.

19. The organometallic photoresist of claim 18, wherein substituted comprises fluorine.

20. The organometallic photoresist of claim 15, wherein the photoresist is for extreme ultraviolet lithography, deep ultraviolet lithography, e-beam radiation, X-ray radiation, or ion-beam radiation.
